(19) United States
(12) Patent Application Publication
(10) Pub. No.: US 2002/0158315 A1
(43) Pub. Date: Oct. 31, 2002

(54) Lead frame having semiconductor device mounted thereon and method for fabricating the same

(75) Inventor: Yoshio Karube, Yamagata (JP)

Correspondence Address: Patent Group, Hutchins, Wheeler & Dittmar, 101 Federal Street, Boston, MA, 02110, US

(73) Assignee: NEC Corporation

(21) Appl. No.: 10/128,204

(22) Filed: Apr. 23, 2002

(30) Foreign Application Priority Data
Apr. 25, 2001 (JP) 127813/2001

(51) Int. Cl. H01L 21/44; H01L 23/495; H01L 21/50

(52) U.S. Cl. 257/666; 438/123; 257/686; 438/109; 257/667; 438/124; 257/676

(57) ABSTRACT

Upper and lower protective protruded portions are formed on an upper and lower surfaces of the lead frame to prevent breakage of resin mold or bending of terminals of semiconductor devices 2 mounted on a lead frame 1 during transportation of the lead frame between fabrication steps thereof. The regions of the upper and lower protective protruded portions are located between adjacent ones of the semiconductor devices. Those protruded portions are formed simultaneously with the resin sealing of the semiconductor devices by using the same resin material.

### BACKGROUND OF THE INVENTION

1. Field of the Invention

The present invention relates to a lead frame having semiconductor devices mounted thereon and a method for fabricating the same lead frame and, particularly, to a lead frame on which semiconductor devices having protective protrusions are mounted and a method for fabricating the same lead frame.

2. Description of the Prior Art

A conventional method for fabricating a hoop-like lead frame on which a plurality of semiconductor devices such as IC chips are mounted includes the steps of die-bonding the semiconductor devices onto the hoop-like lead frame, sealing the semiconductor devices with a resin material by using metal mold halves, rolling the lead frame having the resin sealed semiconductor devices on a reel and the rolled lead frame is transported to a next step such as, for example, a flash removing step of removing flashes of the sealing resin molds or a solder-plating step of plating terminals of the lead frame with a solder material.

FIG. 12 is an enlarged side view of a hoop-like lead frame 1 having semiconductor devices 2 mounted thereon and rolled on a reel (not shown). As shown in FIG. 12, in rolling the hoop-like lead frame 1, which has the semiconductor devices 2 mounted thereon, on the reel, force is exerted on the lead frame in a direction shown by an arrow, so that the semiconductor devices 2 in adjacent rolls are interfered each other, resulting in a problem that the sealing resin molds thereof are broken and/or terminals 10 of the lead frame are bent. A portion of the lead frame 1 on which one semiconductor device 2 is mounted is shown in FIG. 13.

As will be described later, there is a similar problem in a conventional method for fabricating semiconductor devices by using a strip-like lead frame, in which a plurality of strip-like lead frames having semiconductor devices mounted thereon are piled up in a magazine and the magazine is transported to a next fabrication step.

In the method for fabricating semiconductor devices on such strip-like lead frame or hoop-like lead frame, it is important to prevent the sealing resin molds of the semiconductor devices from being broken and the terminals thereof from being bent.

In order to solve such problem, it has been usual that an interlayer paper sheet 13 for protecting the semiconductor devices 2 on the hoop-like lead frame 1 is provided on the semiconductor devices 2 and the lead frame 1 together with the interlayer paper sheet 13 is rolled on a reel 5 as shown in FIG. 14. FIG. 15 is an enlarged side view showing a rolled lead frame together with the interlayer paper sheet 13. By arranging the interlayer paper sheet 13 between adjacent rolls, interference between the semiconductor devices 2 is prevented. Incidentally, FIG. 13 is an enlarged perspective view of the semiconductor device 2 on the hoop-like lead frame 1.

JP-H5-138699-A discloses another measures against the above-mentioned problem. In the technique disclosed therein, a tie member is provided between adjacent resin sealed semiconductor elements mounted on a hoop-like lead frame such that the tie member crosses support members provided on both sides of the elements to prevent a semiconductor element in a certain layer from being dropped in between adjacent semiconductor elements in a layer adjacent to the certain layer when the hoop-like lead frame is rolled on a reel, so that breakage of the sealing resin molds and/or deformation of lead terminals of the lead frame is prevented.

JP-H11-340396-A discloses a technique for preventing deformation of terminals of a hoop-like lead frame when upsetting and down setting of the terminals are performed. In this technique, protruded portions are provided on both surfaces of the lead frame.

On the other hand, JU-H5-28034-A discloses a technique in which strip-like spacers are provided on both edges of a single line lead frame having a plurality of semiconductor devices mounted thereon in one line.

As mentioned above, in the conventional method shown in FIG. 14 in which the interlayer paper sheet is provided between adjacent rolls of the hoop-like lead frame, a device for supplying the interlayer paper sheet is necessary, causing a whole device for performing the method to be complicated and expensive. Furthermore, it is necessary in a subsequent step to cut out semiconductor devices while peeling the interlayer paper sheet off. Such device usually has a complicated structure and is expensive. In addition, the interlayer paper sheet peeled off becomes waste matter.

Since, in JP-H5-138699-A, the tie members are provided on only an upper side of the hoop-like lead frame, the tie members on a certain roll of the lead frame interfere with those on another roll when the lead frame having the semiconductor devices mounted thereon is rolled on the reel. In, for example, a semiconductor chip such as QFN (Quad Flat Non-Lead) type semiconductor chip, which is thin and has only an upper side thereof resin-sealed, there are defects that (i) it is impossible to roll the lead frame on the reel without contact of the terminals in a layer with a rear surface of the semiconductor device in a layer adjacent thereto, since terminals on a rear surface side of the semiconductor device are exposed, and, therefore, the terminals on the rear surface side may be scratched, causing an outer appearance of the chip to be degraded and (ii) it is impossible to completely prevent breakage of the sealing resin molds and bending of the terminals of the lead frame since the semiconductor device and the tie members are interfered with each other.

In the structure disclosed in JP-H11-340396-A, since height of the protruded portion is smaller than that of the sealing resin mold, it is impossible to avoid breakage of the sealing resin mold and deformation of the terminals because the semiconductor devices are interfered each other when the lead frame having the resin-sealed semiconductor devices mounted thereon are rolled up.

Furthermore, in the structure disclosed in JU-H5-28034-A, the above problems can be solved when the hoop-like lead frame is a single line hoop-like lead frame. However, when it is a plural line, hoop-like lead frame in which semiconductor devices are arranged in a plurality of lines, the width of the hoop-like lead frame becomes larger than that of the single line lead frame. Therefore, when the spacers are provided on the opposite edges of the lead frame, a center portion of the lead frame is drooped and the semiconductor devices mounted thereon are interfered with each other. Consequently, it is difficult to prevent the breakage of the sealing resin mold, etc.

### SUMMARY OF THE INVENTION

An object of the present invention is to provide a lead frame on which semiconductor devices are mounted, which can prevent interference between the semiconductor devices by protruded portions provided on both of an upper and a lower side of a hoop-like or strip-like lead frame simultaneously with resin-sealing of the semiconductor devices in the resin-sealing step of a fabrication method of semiconductor device.

Another object of the present invention is to provide the method for fabricating the same lead frame.

According to the present invention, a lead frame is featured by comprising a lead frame having a plurality of semiconductor chips mounted thereon and extending in one direction, sealing resin molds having a constant height from a principal surface of the lead frame for sealing the plurality of respective the semiconductor chips with a resin material, upper protruded portions formed of the same resin material on the principal surface of the lead frame in positions between adjacent ones of the sealing resin molds simultaneously with the formation of the sealing resin molds and lower protruded portions formed of the same resin material on a surface of the lead frame opposite to the principal surface thereof in positions corresponding to the positions of the upper protruded portions, simultaneously with the formation of the sealing resin molds.

A plurality of through-holes for connecting the upper protruded portions to the lower protruded portions, respectively, may be formed in the lead frame. In order to prevent peeling off of the protruded portions from the lead frame, a diameter of each through-hole may be smaller than a size of the upper protruded portion as well as the lower protruded portion.

Moreover, height of the upper protruded portion from the principal surface of the lead frame may be larger than that of the sealing resin mold. Further, a configuration of the upper protruded portion in a plan view may be the same as that of the lower protruded portion or may be different from that of the lower protruded portion.

The lead frame may be a hoop-like lead frame or strip-like lead frame.

In the case of the strip-like lead frame, a plurality of the upper protruded portions and a plurality of said lower protruded portions may be provided between adjacent ones of the sealing resin molds.

Alternatively, the upper protruded portion and the lower protruded portion may be provided in other regions than those each between adjacent ones of the plurality of the resin seals. Further, a plurality of the semiconductor chips may be arranged in a direction perpendicular to the extending direction of the lead frame.

In the case of the strip-like lead frame, height of the upper protruded portion from the principal surface of the lead frame may be the same as that of the sealing resin mold.

In the present lead frame, cross sectional configurations of the upper protruded portion and the lower protruded portion may be trapezoidal, respectively.

In the present invention, the semiconductor chip may be a QFN type semiconductor chip having an upper surface sealed by the resin material and terminals exposed on a lower surface side thereof.

According to the present invention, a method for fabricating a lead frame having semiconductor devices mounted thereon is featured by comprising the steps of mounting a plurality of semiconductor chips on the lead frame, sealing the plurality of the semiconductor chips mounted on the lead frame with a resin material, forming upper protruded portions of a resin material, which is the same as the resin material used in the sealing step, on an upper surface of the lead frame in regions each between adjacent ones of the plurality of the semiconductor chips, simultaneously in the sealing step and forming lower protruded portions of a resin material, which is the same as the resin material used in the sealing step, on a lower surface of the lead frame in regions each between adjacent ones of the plurality of the semiconductor chips, simultaneously in the sealing step.

In the above-mentioned method, a plurality of through-holes each for connecting the upper protruded portion to the lower protruded portion are formed in the lead frame and runners provided in a metal mold used in the sealing step are commonly connected to regions of the semiconductor chips and to regions of the through-holes.

In the above-mentioned method, the resin sealing is performed such that QFN type semiconductor chips are constructed as the semiconductor devices.

Furthermore, after the sealing step, the step of solder-plating terminals of the semiconductor devices, which are exposed on the side of the lower surface of the lead frame is further included.

As mentioned above, according to the present invention, it is possible to prevent breakage of the sealing resin mold of the semiconductor device and/or bending of the terminal of the lead frame when the strip type lead frames are piled up or the hoop-like lead frame is rolled. The lower protruded portion can prevent the upper protruded portion from being dropped from the lead frame and can maintain a gap between the semiconductor devices when the lead frame is rolled. Further, when the size of the semiconductor device is large, it is possible to provide a plurality of protruded portions on both surfaces of the lead frame such that the protruded portions surround the semiconductor device.

### BRIEF DESCRIPTION OF THE DRAWINGS

FIG. 1 is a perspective view of a hoop-like lead frame having protruded portions provided thereon and being rolled up on a reel, according to a first embodiment of the present invention;

FIG. 2A is a plan view showing a state of the hoop-like lead frame according to the first embodiment in which a resin sealing is performed;

FIG. 2B is an enlarged cross section taken along a line A-A in FIG. 2A;

FIG. 2C is a plan view of FIG. 2B;

FIG. 3 is a side view of the hoop-like lead frame shown in FIG. 2A in a width direction thereof;

FIG. 4 is a side view similar to FIG. 3, showing irregular overlapping state of the hoop-like lead frame of the first embodiment;

FIG. 5 is a perspective view of a conventional strip-like lead frame having semiconductor devices arranged in three lines in a longitudinal direction of the lead frame;

FIG. 6 is a plan view of a rear surface of the resin-sealed semiconductor device of a conventional strip-like lead frame;

FIG. 7 is a perspective view of a magazine for transporting conventional strip-like lead frames between conventional fabrication steps;

FIG. 8 is a side view showing conventional strip-like lead frames overlapped each other;

FIG. 9 is a side view showing overlapped strip-like lead frames according to a second embodiment of the present invention;

FIG. 10 is a perspective view of a portion of a strip-like lead frame according to a third embodiment of the present invention, on which large size semiconductor devices are mounted;

FIG. 11 is a side view of the strip-like lead frames shown in FIG. 10, showing the overlapped state of the lead frames;

FIG. 12 is an enlarged side view of a conventional hoop-like lead frame, in a rolled state on a reel;

FIG. 13 is an enlarged perspective view of a portion of the conventional lead frame in the vicinity of a semiconductor device mounted thereon;

FIG. 14 is a perspective view of a conventional hoop-like lead frame, showing a state where the lead frame is rolled on a reel together with an interlayer paper sheet; and

FIG. 15 is an enlarged side view of the hoop-like lead frame rolled on the reel together with the interlayer paper sheet.

### DETAILED DESCRIPTION OF THE PREFERRED EMBODIMENTS

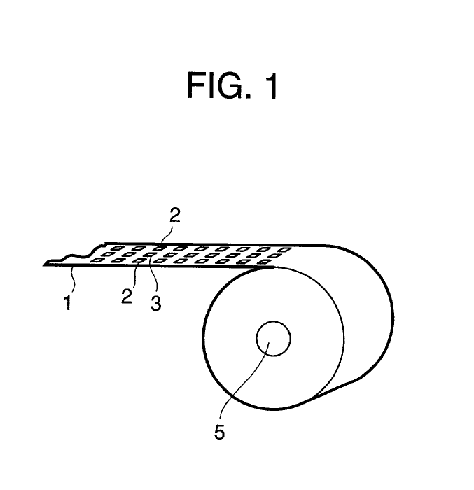

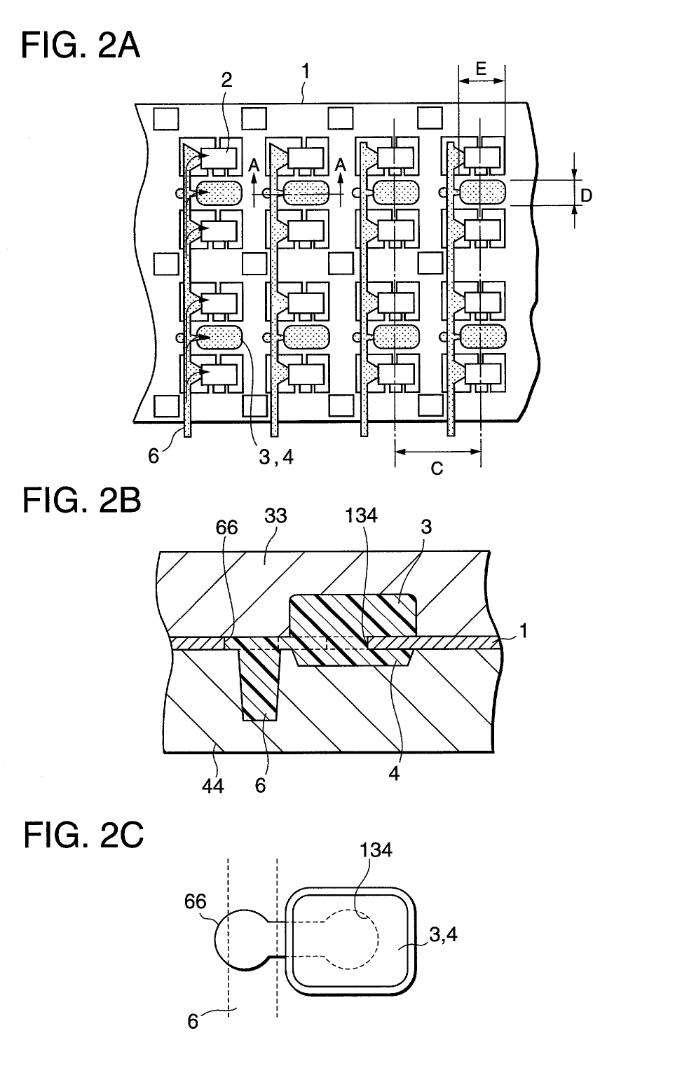

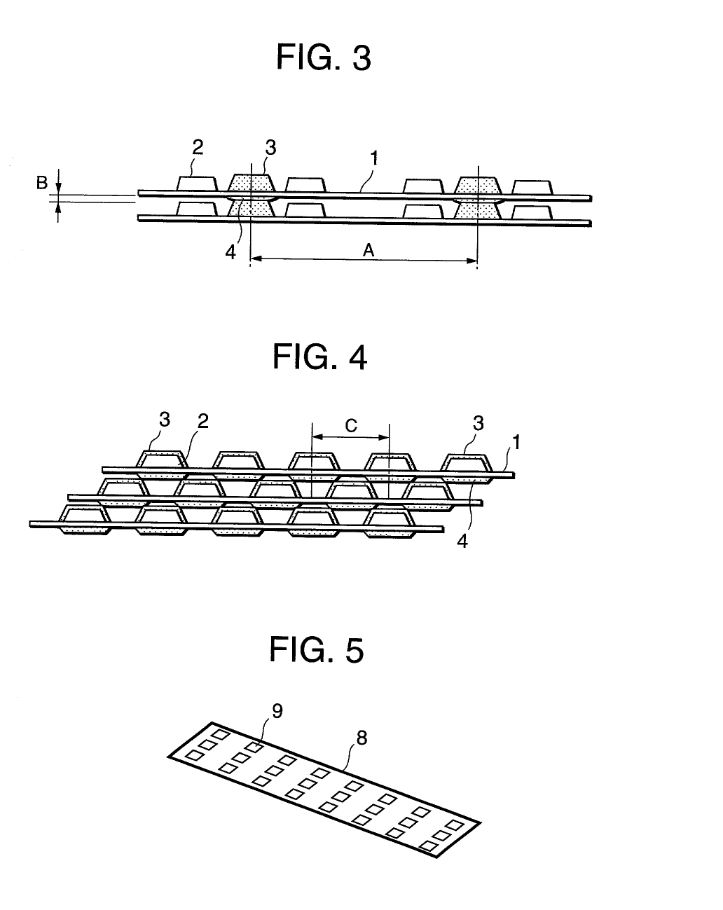

As shown in FIG. 1, a hoop-like lead frame 1 according to a first embodiment of the present invention, which has two lines of semiconductor devices 2 mounted thereon, is rolled on a reel 5. On the lead frame 1, which may be formed of a Cu-alloy, protruded portions 3 are also formed. In FIG. 2A, an example of the hoop-like lead frame 1 of the present invention, which has four lines of semiconductor devices mounted thereon, is shown. After the semiconductor devices 1 are die-bonded to the hoop-like lead frame 1, a resin sealing is performed as shown in FIG. 2A through FIG. 2C and FIG. 3. This resin-sealing step is usually performed by setting metal mold halves such that the metal mold halves cover the semiconductor devices and pouring sealing resin such as epoxy resin into the metal mold. In the first embodiment of the present invention, however, the metal mold used in the resin-sealing step has, in addition to cavities for the resin sealing of the semiconductor devices, cavities for forming protruded portions 3 and 4 of resin between adjacent semiconductor devices in each line as shown in FIG. 2A through FIG. 2C.

The resin-sealing step in a fabrication method of the semiconductor device will be described in detail with reference to FIG. 2A through FIG. 2C. The semiconductor devices are die-bonded to die pad portions of the hoop-like lead frame 1. Although not shown, bonding pads of the semiconductor device are connected to terminals of the lead frame by bonding wires as usual. FIG. 2A shows an example in which two pairs of the semiconductor devices 2 arranged in a width direction of the lead frame are die-bonded as a unit and a plurality of the units are arranged in a longitudinal direction of the lead frame at a predetermined interval.

Thereafter, the resin sealing is performed by using the metal mold. The metal mold includes metal mold halves 33 and 34 for providing the cavities for the resin-sealing of the semiconductor devices and the cavities for forming the protruded portions between adjacent ones of the paired semiconductor devices. Such metal mold is set in a predetermined position such that the metal mold covers the semiconductor devices on the hoop-like lead frame. The resin material is poured into the cavities formed in the upper metal mold half 33 and the lower metal mold half 44 through runners 6 in directions shown by arrows in FIG. 2A, so that the protruded resin portions 3 and 4 are formed simultaneously with the formation of the sealing resin molds of the semiconductor devices. A small through hole 134 is formed in a position of the lead frame 1 in which each of the protruded portions is formed so that the upper protruded portion 3 becomes integral with the lower protruded portion 4. The diameter of the through hole 134 is smaller than an outer diameter of the upper and lower protruded portions 3 and 4 to prevent the protruded portion from dropping from the lead frame. In the disclosed example, the through hole 134 is a part of a dumbbell-shaped opening 66, which has an elongated opening having enlarged, rounded ends. The dumbbell-shaped opening 66 is used to carry the resin from the runners 6 to the cavities for the protruded resin portions 3 and 4.

The upper and lower protruded portions will be described with reference to FIG. 3, which is a side view of the lead frame in the width direction thereof after the formation of the sealing resin mold and the lead frame is rolled regularly. The protruded portions are provided on both upper and lower sides of the hoop-like lead frame 1 and an upper surface of the upper protruded portion 3 is higher than an upper surface of the sealing resin mold of the semiconductor device 2. The lower protruded portion 4 is provided to prevent the upper protruded portion 3 from being dropped from the lead frame and to provide a gap B between a lower surface of the lead frame in an upper layer and an upper surface of the semiconductor device 2 in a lower layer when the upper layer lead frame and the lower layer lead frame are overlapped by rolling. A plurality of pairs of the protruded portions 3 and 4 are provided at arbitrary positions within a region having width A, which is twice a pitch of the semiconductor devices in the width direction thereof as shown in FIG. 3.

FIG. 4 is a side view of the hoop-like lead frame 1 shown in FIG. 2, which is rolled irregularly in the width direction thereof. Outer sizes of the protruded portions 3 and 4 are determined such that the semiconductor devices 2 are not interfered with each other even when the lead frame is rolled with an upper layer being deviated from a lower layer by a distance, which is a half of the pitch C of the semiconductor devices in the longitudinal direction of the lead frame as shown in FIG. 4. Incidentally, configurations of the upper and lower protruded portions 3 and 4 may be different or identical. However, height of the lower protruded portion 4 from the upper surface of the lead frame 1 is smaller than that of the upper protruded portion 3 from the lower surface of the lead frame 1. Particularly, the height of the lower protruded portion 4 is preferably not smaller than a difference in height between the upper protruded portion 3 and the semiconductor device 2, as shown in FIG. 3.

An example of practical values of the sizes of the protruded portions in this embodiment will be described with reference to FIG. 2A, FIG. 3 and FIG. 4. The hoop-like lead frame 1 is 0.125 mm thick, the semiconductor device 2 is 0.5 mm high, the upper protruded portion 3 is 0.625 mm high, the lower protruded portion 4 is 0.2 mm high, the gap B between the lower surface of the upper layer lead frame 1 and the upper surface of the lower layer semiconductor device 2 is 0.325 mm, the lateral pitch C between the protruded portions 3 and 4 and adjacent protruded portions 3 and 4 is 3.2 mm, a lateral size E of the upper protruded portion 3 as well as the lower protruded portion 4 is 1.8 mm and a longitudinal size D of the upper protruded portion 3 as well as the lower protruded portion 4 is 1.6 mm.

In this embodiment, the upper and lower protruded portions 3 and 4 are provided between the semiconductor devices 2 on both sides of the hoop-like lead frame 1 with the conditions that C is 3.2 mm, E is 1.8 mm, D is 1.6 mm and a gap (C-E) given to the pitch of the protruded portions 3 and 4 in the lateral direction is only 1.4 mm. Therefore, the paired protruded portions 3 and 4 in one layer of the rolled hoop-like lead frame 1 becomes in contact with the paired protruded portion in layers above and below the one layer without dropping in the region between adjacent pairs of the protruded portions in the underlying layer as shown in FIG. 4. Thus, it is possible to provide the gap between the upper and lower semiconductor device, which is large enough to reliably prevent the interference between the semiconductor devices and the interference between the semiconductor device and the lead frame 1 to thereby protect the semiconductor devices 2. Incidentally, the described values are mere examples and not limited thereto.

According to this embodiment, the following merits can be obtained:

By the provision of the protruded portion formed of the same resin material as that of the sealing resin of the semiconductor device in the same step of forming the sealing resin molds of the semiconductor devices, the semiconductor devices do not directly contact with each other when the lead frame is rolled, so that it becomes possible to prevent breakage and/or cracking of the sealing resin mold of the semiconductor device and bending of the terminals of the lead frame.

Since there is no interlayer paper sheet used, it is possible to reduce the unit cost of the semiconductor device.

The structure of the semiconductor device fabrication device becomes simple and it is possible to reduce the cost thereof.

Since the interlayer paper sheet is unnecessary, it is possible to reduce the amount of waste.

Since the formation of the protruded portions is performed simultaneously with the formation of the sealing resin molds of the semiconductor devices, there is no need of adding any new fabrication step.

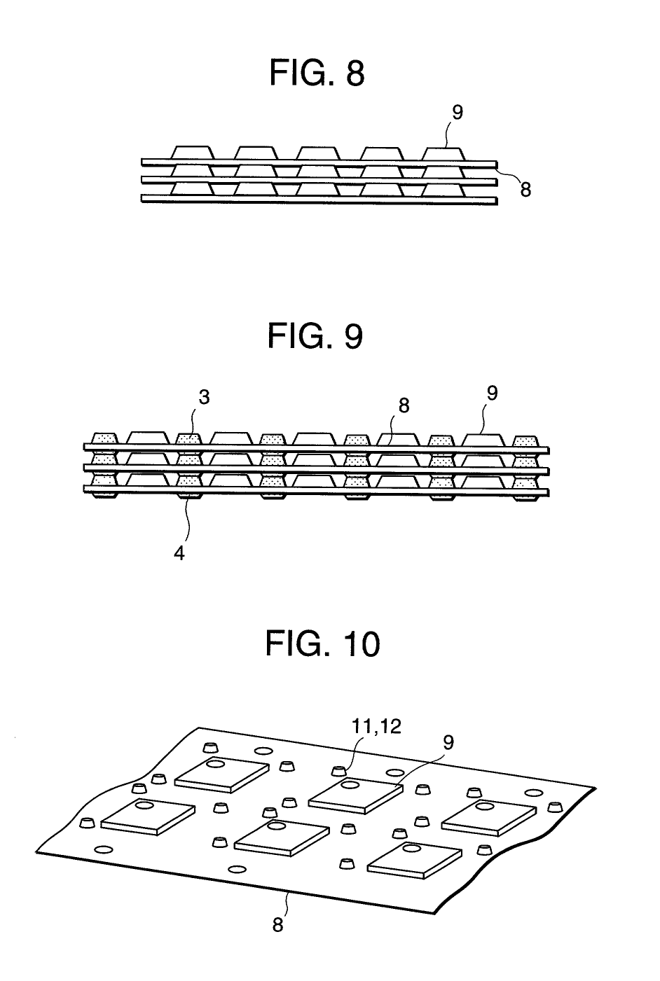

Now, a second embodiment of the present invention will be described in which the present invention is applied to a strip-like lead frame for the QFN type semiconductor device. Before describing the second embodiment, the conventional strip-like lead frame 8 on which the QFN type semiconductor devices 9 are mounted will be described with reference to FIG. 5 to FIG. 8.

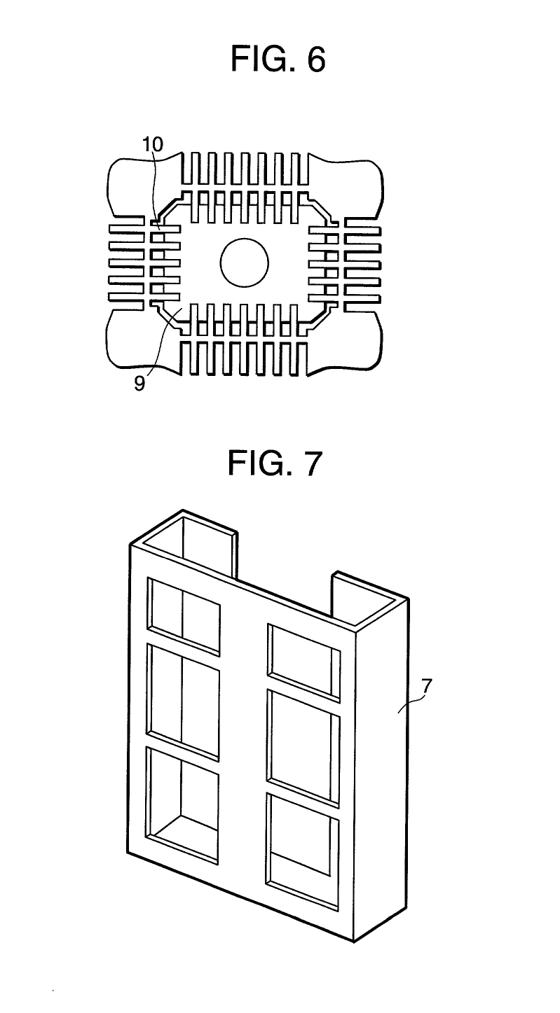

In the conventional QFN type semiconductor device, only an upper surface thereof is sealed with resin and terminals 10 of the lead frame are exposed in a lower surface thereof as shown in FIG. 6. After the resin-sealing step is completed, the strip-like lead frames 8 are plated with solder and then the lead frames 8 are piled up in a vertical magazine 7 shown in FIG. 7 and transported between fabrication steps. Since the lead frames are strip-like and housed in the magazine 7, rear surfaces of succeeding semiconductor devices 9 on a newly piled lead frame are interfered by front surfaces of semiconductor devices 9 on an already piled lead frame, when the new lead frame is put in the magazine. Therefore, the solder-plated surface of the terminals 10 shown in FIG. 6 and the front surface of the semiconductor devices 9 are scrubbed each other, so that the solder on surfaces of the terminals of the lead frame 8 is transferred to the front surface of the semiconductor devices 9 of the next lead frame 8. Therefore, the outer appearance of the semiconductor devices is degraded, causing the yield thereof to be lowered.

In the second embodiment of the present invention, protruded portions 3 and 4 of resin are formed on both surfaces of the strip-like lead frame 8 in regions between resin sealed QFN type semiconductor devices 9 mounted thereon in the resin sealing step of the semiconductor devices, as shown in FIG. 9. The resin sealing of the semiconductor devices and the formation of the protruded portions can be performed by a method similar to that described in the first embodiment.

Since each pair of the upper and lower protruded portions 3 and 4 is provided between the semiconductor devices in the second embodiment, height of the upper protruded portion may be the same as that of the QFN type semiconductor device 9. As is clear from FIG. 9, there is no interference between the soldered surface of the terminals 10 and the semiconductor devices 9 when the strip-like lead frames are piled up, so that the yield of the semiconductor device 9 is improved.

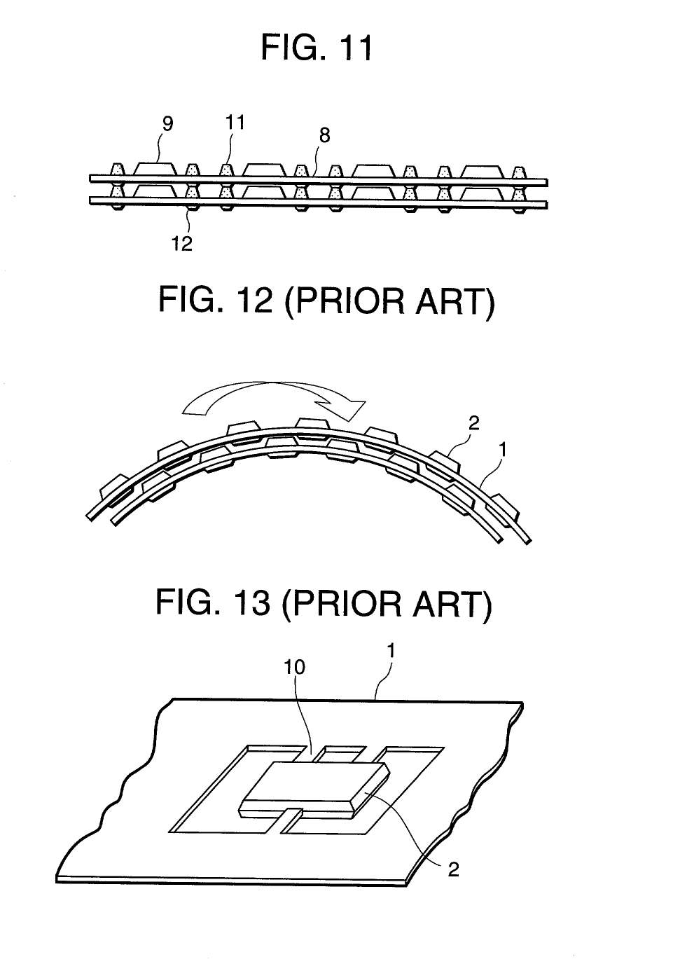

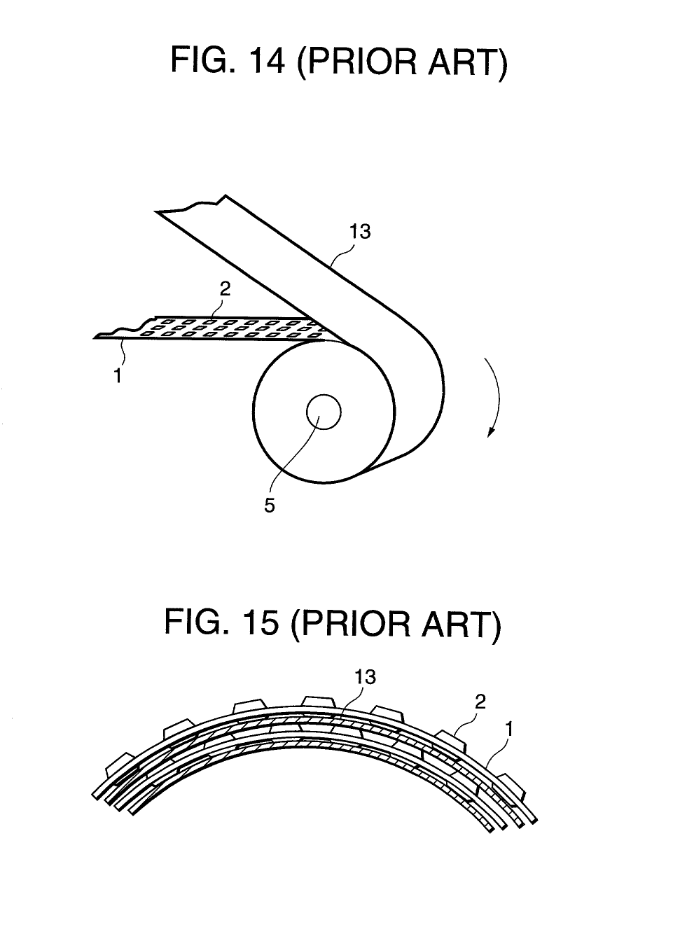

As a third embodiment of the present invention, a case where large size semiconductor devices are mounted on a strip-like lead frame will be described. FIG. 10 is a perspective view of the third embodiment of the present invention in which large size semiconductor devices 9 such as very large scale integrated circuits having each side of 50 mm or more are mounted on a strip-like lead frame 8. In the third embodiment, a plurality of truncated cone shaped upper protruded portions 11 each having height not smaller than that of the semiconductor chip are provided on an upper surface of the lead frame 8 such that the protruded portions 11 surround each of the semiconductor chips 9 and lower protruded portions 12 are provided correspondingly to the upper protruded portions 11 in a resin sealing step of the semiconductor chips 9, as shown in FIG. 10. Therefore, there is no interference between the semiconductor devices 9 when they are piled up in the magazine 7 as shown in FIG. 11, so that the problem mentioned previously can be solved. The configuration of the protruded portion is not limited to the truncated cone and the configuration of the upper protruded portion may or may not be analogous to that of the lower protruded portion.

As described hereinbefore, the following merits can be obtained by employing the lead frame having the protective protruded portions formed thereon:

(i) The semiconductor devices do not directly contact with each other when the lead frame is rolled, so that it becomes possible to prevent breakage and/or cracking of the sealing resin mold of the semiconductor device and bending of the terminals of the lead frame.

(ii) Since there is no interlayer paper sheet used, it is possible to reduce the unit cost of the semiconductor device and, since the structure of the device for fabricating semiconductor device becomes simple, it is possible to reduce the cost thereof.

(iii) Since the interlayer paper sheet is unnecessary, it is possible to reduce the amount of waste.

(iv) Since the formation of the protruded portions is performed simultaneously with the formation of the sealing resin molds of the semiconductor devices, there is no need of adding any new fabrication step.

In the case of the lead frame on which semiconductor devices such as QFN type semiconductor devices only upper sides thereof of which are resin-sealed are mounted, terminals of the lead frame exposed in the rear surface side, when the lead frame is rolled, are not in contact with the upper surface of the semiconductor devices by means of the protruded portions and, therefore, the solder plating on the terminals can be protected.

What is claimed is:

1. A lead frame for semiconductor chip, comprising:
a lead frame having a plurality of semiconductor devices mounted on a principal surface thereof and extending in one direction;
sealing resin molds for sealing the plurality of said semiconductor devices with a resin material, each sealing resin mold having a constant height from said principal surface of said lead frame;
upper protruded portions formed of said resin material on said principal surface of said lead frame in positions each between adjacent ones of said sealing resin molds simultaneously with the formation of said sealing resin molds; and
lower protruded portions formed of said resin material on a surface of said lead frame opposite to said principal surface of said lead frame in positions corresponding to said positions of said upper protruded portions, simultaneously with the formation of said sealing resin molds.

2. A lead frame as claimed in claim 1, wherein a plurality of through-holes for connecting said upper protruded portions to said lower protruded portions, respectively, are formed in said lead frame.

3. A lead frame as claimed in claim 2, wherein a diameter of each said through-hole is smaller than a size of said upper protruded portion as well as said lower protruded portion.

4. A lead frame as claimed in claim 1, wherein the height of said upper protruded portion from said principal surface of said lead frame is larger than that of said sealing resin mold.

5. A lead frame as claimed in claim 1, wherein a configuration of said upper protruded portion in a plan view is the same as that of said lower protruded portion.

6. A lead frame as claimed in claim 1, wherein a configuration of said upper protruded portion in a plan view is different from that of said lower protruded portion.

7. A lead frame as claimed in claim 1, wherein said lead frame is a hoop-like lead frame.

8. A lead frame as claimed in claim 1, wherein said lead frame is a strip-like lead frame.

9. A lead frame as claimed in claim 8, wherein a plurality of said upper protruded portions and a plurality of said lower protruded portions are provided between adjacent ones of said sealing resin molds.

10. A lead frame as claimed in claim 1, wherein said upper protruded portion and said lower protruded portion are provided in other regions than regions between adjacent ones of the plurality of said sealing resin molds.

11. A lead frame as claimed in claim 1, wherein a plurality of said semiconductor chips are arranged in a direction perpendicular to the extending direction of said lead frame.

12. A lead frame as claimed in claim 8, wherein the height of said upper protruded portion from said principal surface of said lead frame is the same as that of said sealing resin mold.

13. A lead frame as claimed in claim 1, wherein cross sectional configurations of said upper protruded portion and said lower protruded portion are trapezoidal, respectively.

14. A lead frame as claimed in claim 1, wherein said semiconductor chip is a QFN type semiconductor chip having an upper surface sealed by said resin material and terminals of said lead frame exposed on a lower surface side thereof.

15. A method for fabricating a lead frame having semiconductor devices mounted thereon, comprising the steps of:
mounting a plurality of semiconductor chips on said lead frame;
sealing the plurality of said semiconductor chips mounted on said lead frame with a resin material;
forming upper protruded portions of the resin material on an upper surface of said lead frame in regions between adjacent ones of the plurality of said semiconductor chips, simultaneously in the sealing step; and
forming lower protruded portions of the resin material on a lower surface of said lead frame in regions between adjacent ones of the plurality of said semiconductor chips, simultaneously in the sealing step.

16. A method as claimed in claim 15, wherein a plurality of through-holes each for connecting said upper protruded portion to said lower protruded portion are formed in said lead frame and runners provided in a metal mold used in the sealing step is commonly connected to regions of said semiconductor chips and to regions of said through-holes.

17. A method as claimed in claim 15, wherein said semiconductor chip is a QFN type semiconductor chip.

18. A method as claimed in claim 17, further comprising, after the sealing step, the step of solder-plating terminals of said lead frame, which are exposed on the side of said lower surface of said lead frame.
